(19) United States
(12) Patent Application Publication
(10) Pub. No.: US 2026/0212482 A1
(43) Pub. Date: Jul. 23, 2026

(54) SUPPORT MARK INSPECTION EQUIPMENT OF SEMICONDUCTOR WAFER, METHOD OF DETERMINING SUPPORT MARK, AND PROGRAM OF DETERMINING SUPPORT MARK

(71) Applicant: Renesas Electronics Corporation, Tokyo (JP)

(72) Inventors: Yoshikazu NAGAMURA, Tokyo (JP); Tomonari YAMAGUCHI, Tokyo (JP)

(21) Appl. No.: 19/453,631

(22) Filed: Jan. 20, 2026

(30) Foreign Application Priority Data
Jan. 23, 2025 (JP) 2025-010051

(51) Int. Cl. G06T 7/00; G06T 5/60

(52) U.S. Cl. CPC G06T 7/0004; G06T 5/60; G06T 2207/20081; G06T 2207/30148

(57) ABSTRACT

A support mark inspection equipment includes: an input unit for obtaining an inspection image of a wafer; a partial image generating unit for extracting a plurality of partial images, each including a portion where a support portion of a boat contacts the wafer, from the inspection image; a generated image obtaining unit for inputting each of the plurality of partial images into an AI (Artificial Intelligence) model and obtaining a plurality of generated images respectively corresponding to the plurality of partial images; an abnormality determination unit for determining whether a support mark is present in each of the plurality of partial images based on each of the plurality of partial images and each of the plurality of generated images; and an output unit for outputting an inspection result of the support mark.

### CROSS-REFERENCE TO RELATED APPLICATIONS

The disclosure of Japanese Patent Application No. 2025-010051 filed on Jan. 23, 2025, including the specification, drawings and abstract is incorporated herein by reference in its entirety.

### BACKGROUND

This disclosure relates to the semiconductor wafer inspection technology.

The manufacturing process of the semiconductor wafer (hereinafter referred to as “wafer”) includes a heating process. As an example, in the heating process, multiple wafers are inserted into a thermal diffusion furnace and heated. At that time, the multiple wafers are stacked and stored in a container called a boat. Generally, the boat is equipped with multiple columns, each of which has a support portion to hold each wafer. Each wafer is supported by the support portion. As a result, a gap is formed between the wafers, and each wafer is sufficiently heated during the heating process. However, the portion where the support portion contacts the back surface of the wafer may bear the weight of the wafer, resulting in a scratch (hereinafter referred to as “support mark”). This scratch can potentially cause a defect in a chip which is to be created on the wafer. Therefore, it is desirable to efficiently detect the scratch caused by the support portion on a surface of the wafer during the manufacturing process.

There are disclosed techniques listed below.
[Patent Document 1] Japanese Unexamined Patent Application Publication No. 2006-258445

Regarding a wafer inspection technology, for example, Patent Document 1 discloses a wafer inspection method that involves irradiating a wafer containing a small-capacity pattern with a predetermined amount of electron beam to charge it with a polarity that allows charge accumulation in the small-capacity pattern portion, obtaining a secondary electron image emitted from the pattern before the charging voltage of the pattern reaches equilibrium, obtaining a potential contrast signal based on the detected secondary electron signal, and comparing the potential contrast signals obtained from the first and second regions on the wafer to detect the difference in the capacitance of the pattern and thereby inspect the wafer (see “ABSTRACT” of Patent Document 1).

### SUMMARY

According to the technology disclosed in Patent Document 1, inspection of wafers with circuit patterns is possible, but detection of support marks on wafers after the heating process is not. Therefore, there is a need for technology to detect support marks on wafers after the heating process.

This disclosure has been made in view of the above background and can provide technology to detect support marks on wafers after the heating process in certain aspects.

According to one embodiment, a support mark inspection device is provided. The support mark inspection device creates multiple partial images from the wafer inspection image, including areas that contact the support section. Then, the support mark inspection device analyzes each of the multiple partial images to determine the presence or absence of support marks.

According to one embodiment, it is possible to detect support marks on wafers after the heating process. The above and other objectives, features, aspects, and advantages of this disclosure will become apparent from the following detailed description of the disclosure, which is understood in connection with the accompanying drawings.

### BRIEF DESCRIPTION OF THE DRAWINGS

FIG. 1 is a diagram illustrating an example of the mechanism by which support marks are formed on wafers during the heating process.

FIG. 2 is a diagram illustrating an example of a defect in wafer 20 caused by support marks 50 during the heating process.

FIG. 3 is a diagram illustrating an example of the inspection process for support marks 50 by the support mark inspection equipment 100 according to the present embodiment.

FIG. 4 is a diagram illustrating an example of the process for identifying the presence and coordinates of support marks 50 by the support mark inspection equipment 100.

FIG. 5 is a diagram illustrating an example of the functional blocks provided by the support mark inspection equipment 100.

FIG. 6 is a diagram illustrating an example of the hardware configuration provided by the support mark inspection equipment 100.

FIG. 7 is a diagram illustrating an example of the detection process for support marks 50 on wafer 20 by the support mark inspection equipment 100.

FIG. 8 is a diagram illustrating an example of the learning process of AI model 510 and the details of the processing steps S720 to S740.

### DETAILED DESCRIPTION

Below, embodiments of the technical concept related to this disclosure will be described with reference to the drawings. In the following description, the same reference numerals are assigned to the same components. Their names and functions are also the same. Therefore, detailed descriptions of them will not be repeated. Additionally, each embodiment, each modification, each software or program configuration, each hardware configuration, each function, and each process may be selectively combined as appropriate.

### Mechanism Causing Wafer Defect by Support Mark

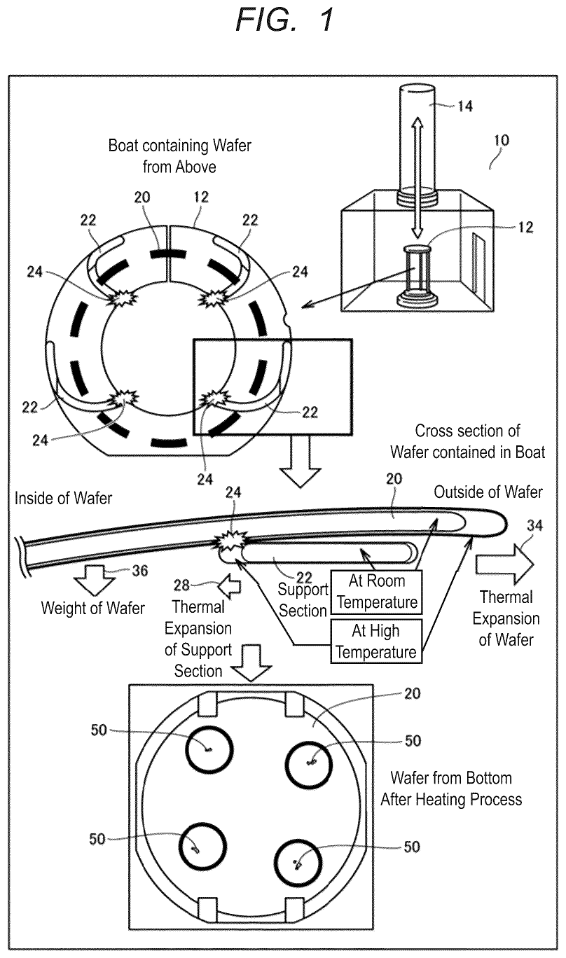

FIG. 1 is a diagram illustrating an example of the mechanism by which support marks are formed on wafers during the heating process. In the heating process, wafer 20 is heated by heating device 10. Heating device 10 heats wafer 20 to adjust its crystal structure.

The heating device 10 mainly comprises a boat 12 capable of stacking and storing wafer 20 and a thermal diffusion furnace 14. Boat 12 is a container capable of stacking and storing multiple wafers 20, made of quartz or similar materials. Additionally, boat 12 is equipped with multiple columns, each having multiple support sections 22 to hold wafer 20. The support portion 22 can be realized in protrusions, depressions, or any other arbitrary shapes. Each wafer 20 is stored in boat 12 in such a way that gaps are formed between the wafers. Boat 12, containing multiple wafers 20, is inserted into thermal diffusion furnace 14. Thermal diffusion furnace 14 heats multiple wafers 20 inserted with boat 12 inside using a heater. The heated wafer 20 is removed from thermal diffusion furnace 14 and undergoes macro image inspection.

When viewing the boat 12 containing the wafer 20 from above, as mentioned earlier, it is evident that wafer 20 stored in boat 12 is supported by multiple support sections 22. In the example of FIG. 1, one wafer 20 is supported by four support sections 22. This is an example, and boat 12 may have any number of support sections 22 to support one wafer 20. Since wafer 20 is placed on multiple support sections 22, the region 24 on the back surface of wafer 20 that contacts the support portion 22 bears the weight of wafer 20. Therefore, these regions 24 are prone to forming the support mark 50.

When viewing the cross-section of the wafer 20 stored in the boat 12, it is evident that wafer 20 expands in the direction of arrow 34 inside thermal diffusion furnace 14. Similarly, support portion 22 also expands in the direction of arrow 28. Furthermore, the wafer 20 bears its own weight in the direction of the arrow 36. These forces affect the region 24, exerting significant pressure. As a result, support marks 50 may form in the region 24.

When viewing the wafer 20 from the bottom after the heating process, it is evident that support marks 50 have formed at four locations on the back surface of wafer 20.

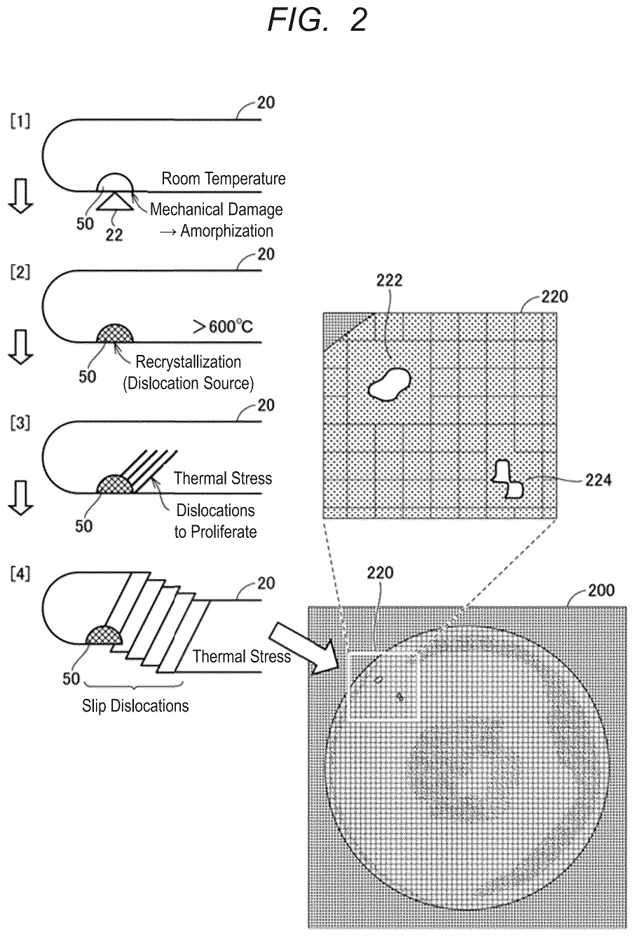

FIG. 2 is a diagram illustrating an example of a defect in wafer 20 caused by support marks 50 during the heating process. As explained with reference to FIG. 1, support marks 50 may form on the surface of wafer 20 stored in boat 12. When wafer 20 with support marks 50 is heated, the area 24 with support marks 50 undergoes recrystallization. This recrystallized portion becomes a dislocation source (also known as a Frank-Read source), causing dislocations to proliferate in other parts of wafer 20. As a result, slip dislocations occur starting from support marks 50. Slip dislocations cause steps to form on wafer 20. Therefore, if a chip is created in the area with support marks 50, it is highly likely that defects will occur in the chip.

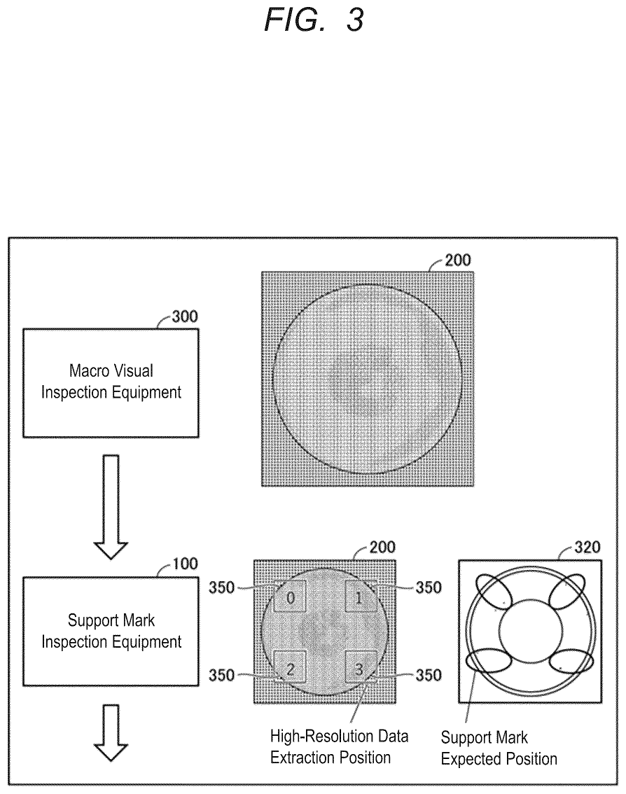

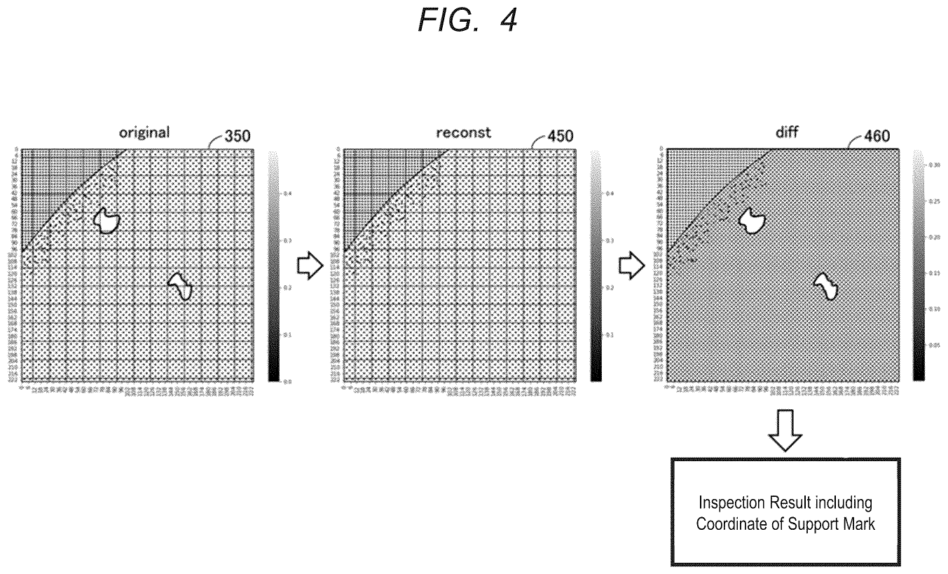

The inspection image 200 is a macro inspection image of the wafer 20 taken after the heating process. Image 220 is an enlarged image of a part of inspection image 200. Areas 222, 224 in the image 220 are parts of the wafer 20 surface with support marks 50. The color of wafer 20 in inspection image 200 is not uniform and has color variations due to various factors such as the light source. The support mark 50 are difficult to distinguish from these color variations. Therefore, it is difficult to accurately determine the presence of support marks 50 in macro image inspection. Thus, the support mark inspection equipment 100 according to the present embodiment determines the presence of the support mark 50 on the surface of the wafer 20 using the procedure shown in FIGS. 3 and 4.

### Mechanism of Support Mark Inspection Device

FIG. 3 is a diagram illustrating an example of the inspection process for support marks 50 by the support mark inspection equipment 100 according to the present embodiment. After the heating process, wafer 20 is inspected by macro appearance inspection device 300. Subsequently, the presence of support marks 50 is inspected by support mark inspection equipment 100. Macro appearance inspection device 300 captures inspection image 200 of wafer 20 and analyzes it to inspect the appearance of wafer 20. Support mark inspection equipment 100 can determine the presence of support marks 50 on the wafer 20 surface, which are difficult to detect with macro appearance inspection device 300.

First, the support mark inspection equipment 100 obtains inspection image 200 from macro appearance inspection device 300. Next, support mark inspection equipment 100 creates multiple partial images 350 from inspection image 200, including the region 24 that contact the support portion 22. In the example of FIG. 3, support mark inspection equipment 100 creates four partial images 350. The region 24 that contacts the support portion 22 can be pre-identified from the specifications 320 of the boat 12. Each partial image 350 can be set as an image of a predetermined range including areas 24 that contact the support portion 22. As an example, support mark inspection equipment 100 can map inspection image 200 into a two-dimensional coordinate space and identify each partial image 350 within the range indicated by coordinates. Support mark inspection equipment 100 can obtain multiple high-resolution (i.e., original resolution) partial images 350 by extracting parts of the original inspection image 200.

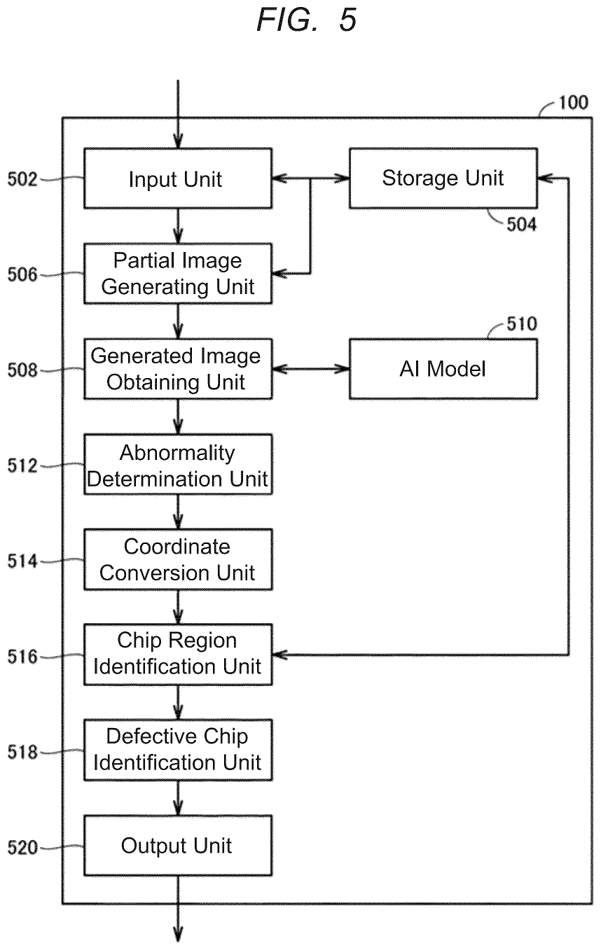

Next, the support mark inspection equipment 100 performs inspections using AI (Artificial Intelligence) model 510 (see FIG. 5) for each of the multiple partial images 350 to determine the presence of support marks 50 in each partial image 350. A specific example of inspection using AI model 510 is explained with reference to FIG. 4. Each of the multiple partial images 350 is an image containing a region where support marks 50 are expected to be present. The support mark inspection equipment 100 can determine the presence or absence of support marks 50 with higher accuracy by inspecting each of the multiple partial images 350, compared to directly inspecting the inspection image 200.

FIG. 4 is a diagram illustrating an example of the process for identifying the presence and coordinates of support marks 50 by the support mark inspection equipment 100. The support mark inspection equipment 100 creates multiple partial images 350 from the inspection image 200. The support mark inspection equipment 100 can create the same number of partial images 350 as the number of support portions 22 from the inspection image 200.

Next, the support mark inspection equipment 100 inputs each of the multiple partial images 350 into the AI model 510. The AI model 510 generates a generated image 450 corresponding to each of the multiple partial images 350. The support mark inspection equipment 100 obtains the generated image 450 corresponding to each of the multiple partial images 350 from the AI model 510. The generated image 450 is an image that mimics the image expected to be obtained when support marks 50 are not present in each of the multiple partial images 350. Hereafter, a partial image 350 where support marks 50 are not present is referred to as a “normal image”. Conversely, a partial image 350 where support marks 50 are present is referred to as an “abnormal image”.

The AI model 510 is a model trained to output a normal image corresponding to the partial image 350 when the partial image 350 is input. The input partial image 350 can be either a normal image or an abnormal image. The AI model 510 outputs a generated image 450, which is an image that mimics a normal image, based on the input partial image 350. As an example, suppose the AI model 510 is input with partial images 350A, 350B, 350C, and 350D. In this case, the AI model 510 generates the generated image 450A based on the partial image 350A. Similarly, the AI model 510 generates each of the generated images 450B, 450C, and 450D based on each of the partial images 350B, 350C, and 350D.

Next, the support mark inspection equipment 100 creates a difference image 460 based on each of the obtained multiple generated images 450 and the partial image 350 corresponding to each of the multiple generated images 450. The difference image 460 is created for each combination of the partial image 350 and the generated image 450. As an example, suppose the AI model 510 generates each of the generated images 450A, 450B, 450C, and 450D from each of the partial images 350A, 350B, 350C, and 350D. In this case, the support mark inspection equipment 100 creates the difference image 460A based on the partial image 350A and the generated image 450A. Similarly, the support mark inspection equipment 100 creates each of the difference images 460B, 460C, and 460D based on each of the partial images 350B, 350C, and 350D and each of the generated images 450B, 450C, and 450D. The partial images 350, generated images 450, and difference images 460 are configured to be divisible into multiple regions by two-dimensional coordinates. The color of each region of the difference image 460 indicates the difference value of the color of the corresponding region of the generated image 450 and the difference image 460.

Next, the support mark inspection equipment 100 analyzes each of the multiple difference images 460 and creates the inspection results for the support marks 50. As an example, the support mark inspection equipment 100 calculates the total value of the value (difference value of corresponding portions of partial image 350 and generated image 450) of each region from the difference image 460. Each region may be represented as a pixel. If the total value is greater than a predetermined threshold (threshold of the total value), the support mark inspection equipment 100 may determine that there is a support mark 50 in the partial image 350 being inspected (i.e., may determine that there is an abnormality in the partial image 350 being inspected). As another example, the support mark inspection equipment 100 may determine whether the value of each region in the difference image 460 is greater than a predetermined threshold (threshold of the difference value of each region). In this case, if there are a predetermined number or more regions with values greater than a predetermined threshold in the difference image 460, the support mark inspection equipment 100 determines that there is a support mark 50 in the partial image 350 being inspected (i.e., determines that there is an abnormality in the partial image 350 being inspected). The predetermined number is any integer of one or more.

If the support mark inspection equipment 100 determines that there is an abnormality in the partial image 350 being inspected, it identifies the coordinate of the portion where the difference value is greater than or equal to a predetermined threshold in the difference image 460 corresponding to the partial image 350 determined to have an abnormality. Hereafter, the portion where the difference value is greater than or equal to a predetermined threshold is referred to as an “abnormal portion”. The abnormal portion is the portion determined to have the support mark 50. The support mark inspection equipment 100 can identify one or more abnormal portions from one difference image 460.

The support mark inspection equipment 100 includes the detecting result of presence or absence of the abnormality and the coordinate of one or more specified abnormal portions in the inspection result of each of the plurality of partial images 350. The coordinate of each abnormal portion may include one or more coordinates. As an example, if the abnormal portion is represented as a rectangle, the coordinates of the abnormal portion may be the coordinates indicating any vertex of the rectangle. Additionally, the coordinates of the abnormal portion may be a set of coordinates of two vertices forming the diagonal of the rectangle. Furthermore, the coordinate of the abnormal portion may be a set of the coordinate of the four vertices of the rectangle. The coordinate of each abnormal portion is the coordinate in the coordinate system of the partial image 350.

Next, the support mark inspection equipment 100 converts the value of the coordinate of the one or more abnormal portions containing the support mark 50 from the value of the coordinate system of the partial image 350 containing the support mark 50 to the value of the coordinate system in the inspection image 200. This allows the position of the one or more abnormal portions in the inspection image 200 to be identified.

Next, the support mark inspection equipment 100 obtains information of the chips formed in alignment on the wafer 20 and identifies a plurality of regions in which the chips are respectively arranged. Next, the support mark inspection equipment 100 identifies the chips which are to be created in the region containing the one or more abnormal portions based on the converted coordinate of the one or more abnormal portions and the plurality of regions where the chips are placed. Hereafter, the chips formed in the region containing the one or more abnormal portions are referred to as “defective chip”.

Finally, the support mark inspection equipment 100 outputs the inspection result of the support mark 50. The inspection result includes information identifying the defective chip. The information identifying the defective chip includes the ID (Identifier) of the defective chip, the position or coordinate information of the defective chip on the wafer 20. Additionally, the inspection result may include the value of the coordinate of the one or more abnormal portions.

As explained with reference to FIGS. 3 and 4, the support mark inspection equipment 100 creates multiple partial images 350 from the inspection image 200, including the region 24 that contacts the support portion 22. Then, the support mark inspection equipment 100 analyzes each of the multiple partial images 350 to determine the presence or absence of support marks 50. By doing so, the support mark inspection equipment 100 can determine the presence or absence of the support mark 50 with even higher accuracy than directly analyzing the inspection image 200.

### Configuration of Support Mark Inspection Device

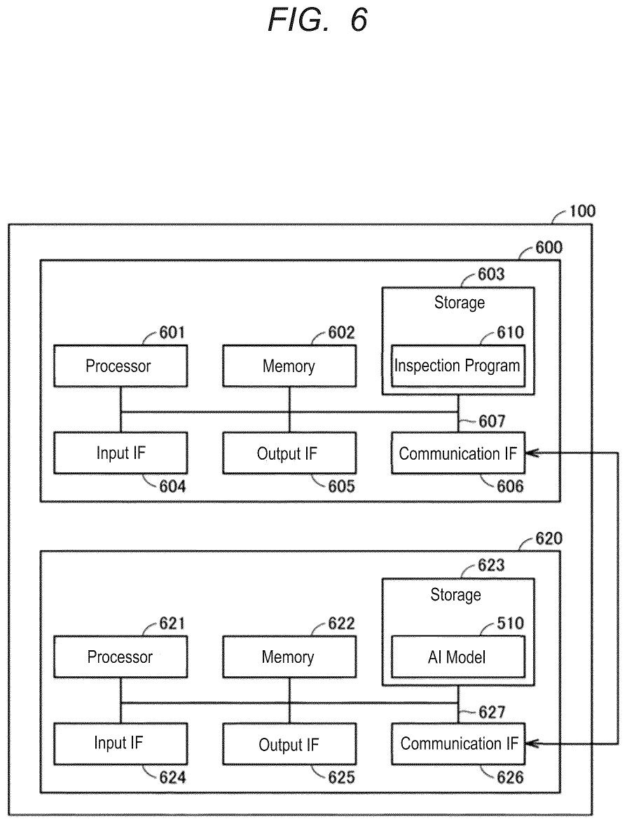

FIG. 5 is a diagram illustrating an example of the functional blocks provided in the support mark inspection equipment 100. Some or all of the functional blocks shown in FIG. 5 may be implemented as a program. In this case, each functional block may be implemented by executing a program on the hardware shown in FIG. 6. Additionally, some or all of the functional blocks shown in FIG. 5 may be implemented as hardware. In this case, the support mark inspection equipment 100 may include some or all of the hardware necessary to implement each functional block shown in FIG. 5, in addition to the hardware shown in FIG. 6.

The support mark inspection equipment 100 includes an input unit 502, a storage unit 504, a partial image generating unit 506, a generated image obtaining unit 508, an AI model 510, an abnormality determination unit 512, a coordinate conversion unit 514, a chip region identification unit 516, a defective chip identification unit 518, and an output unit 520.

The input unit 502 obtains the inspection image 200 of the wafer 20 from the macro appearance inspection device 300. The input unit 502 may request the inspection image 200 from the macro appearance inspection device 300 and obtain one or more inspection images 200 in response to the request. The input unit 502 may refer to the storage of the macro appearance inspection device 300 to obtain one or more inspection images 200. The input unit 502 stores the obtained one or more inspection images 200 in the storage unit 504. Additionally, the input unit 502 may output the obtained one or more inspection images 200 to the partial image generating unit 506.

The storage unit 504 is configured to store one or more inspection images 200. Additionally, the storage unit 504 is configured to store information about the chips created on the wafer 20. The information about the chips includes the position information where each chip is created on the wafer 20. The position information may be expressed in coordinates. Additionally, the position information may indicate the region where the chip is created. The region may include one or more dies or cells. Furthermore, the storage unit 504 is configured to store the inspection results of the support marks 50.

The partial image generating unit 506 extracts multiple partial images 350 from the inspection image 200. The partial image generating unit 506 may read the inspection image 200 stored in the storage unit 504 and extract multiple partial images 350 from the inspection image 200. The partial image generating unit 506 may obtain the inspection image 200 from the input unit 502 and extract multiple partial images 350 from the inspection image 200. The partial image generating unit 506 outputs multiple partial images 350 to the generated image obtaining unit 508.

The generated image obtaining unit 508 inputs each of the multiple partial images 350 into the AI model 510 and acquires each of the multiple generated images 450 corresponding to each of the multiple partial images 350. The generated image obtaining unit 508 outputs multiple partial images 350 and multiple generated images 450 to the abnormality determination unit 512.

The AI model 510 generates each of the multiple generated images 450 from each of the input multiple partial images 350. Then, the AI model 510 outputs each of the multiple generated images 450 to the generated image obtaining unit 508. The AI model 510 may exist within the support mark inspection equipment 100. Alternatively, the AI model 510 may exist outside the support mark inspection equipment 100. In this case, the generated image obtaining unit 508 is configured to communicate with the external AI model 510 via a network.

The AI model 510 may be an autoencoder trained to generate a pseudo-normal image by excluding only the abnormal portions from the input abnormal image. The AI model 510 may be a GAN model trained to generate a pseudo-normal image by excluding only the abnormal portions from the input abnormal image. The AI model 510 may be a diffusion model trained to generate a pseudo-normal image by excluding only the abnormal portions from the input abnormal image. Additionally, the AI model 510 may be PaDiM (Patch distribution modeling) or Patch core.

The abnormality determination unit 512 determines whether there is a support mark 50 in each of the multiple partial images 350 based on each of the multiple partial images 350 and each of the multiple generated images 450. More specifically, as explained with reference to FIG. 4, the abnormality determination unit 512 generates each difference image 460 based on each partial image 350 and each generated image 450. Then, as an example, the abnormality determination unit 512 determines whether the total value of the difference values is equal to or greater than a predetermined threshold. If the total value of the difference values is equal to or greater than the predetermined threshold, the abnormality determination unit 512 determines that there is an abnormality in the partial image 350 under inspection (hereinafter referred to as “inspection target partial image”). As another example, the abnormality determination unit 512 may determine whether the value of each area in the difference image 460 is greater than a predetermined threshold (threshold of difference values for each area). In this case, if there are a predetermined number or more of areas with values greater than the predetermined threshold in the difference image 460, the abnormality determination unit 512 determines that there is a support mark 50 in the partial image 350 under inspection (i.e., determines that there is an abnormality in the partial image 350 under inspection). If the abnormality determination unit 512 determines that there is an abnormality in the partial image 350 under inspection, it may identify the portion where the difference value is equal to or greater than the predetermined threshold in the difference image 460 corresponding to the detected abnormal partial image 350 as the abnormal portion.

The abnormality determination unit 512 outputs the inspection results of each of the multiple partial images 350 to the coordinate conversion unit 514. The abnormality determination unit 512 includes the determination result of the presence or absence of the abnormality and the coordinate of each identified abnormal portion in the inspection result of each of the multiple partial images 350. If there is no support mark 50 in the partial image 350 under inspection, the abnormality determination unit 512 outputs the inspection result indicating the absence of the support mark 50 to the coordinate conversion unit 514.

The coordinate conversion unit 514 converts the coordinate values included in the inspection results of each of the multiple partial images 350 from the coordinate system values of the partial images 350 to the coordinate system values in the inspection image 200. At that time, the inspection results of each of the multiple partial images 350 may be integrated as the inspection result of one wafer 20. The integrated inspection result may include the coordinate values of one or more support marks 50 on the inspection image 200.

The coordinate conversion unit 514 outputs the coordinates of one or more abnormal portions after conversion to chip region identification unit 516. Additionally, the coordinate conversion unit 514 may output the inspection results of each of the multiple partial images 350 to the chip region identification unit 516. Furthermore, the coordinate conversion unit 514 may output the determination results of the presence or absence of anomalies in each of the multiple partial images 350 to the chip region identification unit 516. When the inspection results are integrated, the determination result of the presence or absence of anomalies becomes the determination result of the presence or absence of anomalies in the area corresponding to each partial image 350 of the inspection image 200.

The chip region identification unit 516 refers to storage unit 504 to acquire the inspection image 200 and the information of the chips created on the wafer 20. The chip region identification unit 516 identifies multiple areas on the inspection image 200 where chips are placed from the inspection image 200 and chip information. The chip region identification unit 516 outputs the information of multiple areas on the inspection image 200 where chips are placed to the defective chip identification unit 518. Additionally, the chip region identification unit 516 outputs the information of the coordinates of one or more abnormal portions after conversion obtained from the coordinate conversion unit 514 to the defective chip identification unit 518. Furthermore, the chip region identification unit 516 may output the determination result of the presence or absence of the abnormality in the inspection image 200 or each partial image 350 to the defective chip identification unit 518.

The defective chip identification unit 518 identifies the chip created in the area containing one or more abnormal portions including the support mark 50 based on the coordinates of one or more abnormal portions after conversion and the multiple areas where chips are placed. The defective chip identification unit 518 outputs the information of the chip created in the area containing one or more abnormal portions including the support mark 50 to the output unit 520. Additionally, the defective chip identification unit 518 may output the coordinates of one or more abnormal portions after conversion to the output unit 520. Furthermore, the defective chip identification unit 518 may output the determination result of the presence or absence of anomalies in the inspection image 200 or each partial image 350 to the output unit 520.

The output unit 520 outputs the inspection result of the support mark 50. The inspection result of the support mark 50 includes information for identifying the defective chip. Additionally, the inspection result of the support mark 50 may include the value of the coordinate of the one or more abnormal portions. Furthermore, the inspection result of the support mark 50 may include the determining result of the presence or absence of the abnormality in the inspection image 200 or each partial image 350. The output unit 520 may display the inspection result on a display connected to the support mark inspection equipment 100. Additionally, the output unit 520 may send the inspection result to other devices. Furthermore, the output unit 520 may display the inspection result on a display connected to the support mark inspection equipment 100 and send the inspection result to other devices.

As explained with reference to FIG. 5 (Support for claim 1), the support mark inspection equipment 100 includes an input unit 502 for obtaining the inspection image 200 of the wafer 20, the partial image generating unit 506 for extracting a plurality of partial images 350, each including the portion where the support portion 22 of the boat 12 contacts the wafer 20, from the inspection image 200, the generated image obtaining unit 508 for inputting each of the plurality of partial images 350 into the AI (Artificial Intelligence) model 510 and obtaining the plurality of generated images 450 respectively corresponding to the plurality of partial images 350, an abnormality determination unit 512 for determining whether the support mark 50 is present in each of the plurality of partial images 350 based on each of the plurality of partial images 350 and each of the plurality of generated images 450, and an output unit 520 for outputting the inspection result of the support mark 50.

Additionally (Support for claim 2), the determining whether the support mark 50 is present in each of the plurality of partial images 350 includes specifying the coordinate of the one or more abnormal portions containing the support mark 50 in the partial image 350 containing the support mark 50 based on the detection result of the partial image 350 containing the support mark 50.

Additionally (Support for claim 3), the support mark inspection equipment 100 further includes the coordinate conversion unit 514 for converting the value of the coordinate of the one or more abnormal portions containing the support mark 50 from the value of the coordinate system of the partial image 350 containing the support mark 50 to the value of the coordinate system in the inspection image 200, the chip region identification unit 516 for obtaining information of the chips formed in alignment on the wafer 20 and identifying the plurality of regions in which the chips are respectively arranged, and the defective chip identification unit 518 for identifying the defective chip formed in the region containing the one or more abnormal portions containing the support mark 50 based on the converted coordinate of the one or more abnormal portions and the plurality of regions.

Additionally (Support for claim 4), each of the plurality of generated images 450 is the image that mimics the image expected to be obtained when the support mark 50 is not present in each of the plurality of partial images 350.

Furthermore (Support for claim 5), the determining whether the support mark 50 is present in each of the plurality of partial images 350 includes: generating the difference image 460 between the inspection target partial image 350, which is one of the plurality of partial images 350, and one of the plurality of generated images 450 corresponding to the inspection target partial image 350, determining whether the support mark 50 is present in the inspection target partial image 350 based on the difference value contained in the difference image 460; and extracting one or more coordinates, where the difference value is equal to or greater than the predetermined threshold, from the difference image 460 based on the determining result that the support mark 50 is present in the inspection target partial image 350.

FIG. 6 is a diagram showing an example of the hardware configuration provided by the support mark inspection equipment 100. The support mark inspection equipment 100 may be realized as a system comprising a first device 600 and a second device 620. The first device 600 and the second device 620 may have the same hardware configuration. Additionally, the support mark inspection equipment 100 may be configured as a single device. Furthermore, the support mark inspection equipment 100 may be configured with three or more devices. Moreover, the support mark inspection equipment 100 may be built in a cloud environment.

When the support mark inspection equipment 100 includes the first device 600 and the second device 620, as an example, the second device 620 is used to operate the AI model 510. The first device 600 is used to operate function blocks other than the AI model 510 in FIG. 5. When the support mark inspection equipment 100 is composed of a single device, the single device is used to operate all the function blocks in FIG. 5. When the support mark inspection equipment 100 is composed of three or more devices, each function block in FIG. 5 may be distributed across any device. When the support mark inspection equipment 100 is built in a cloud environment, each function block in FIG. 5 may be placed within a virtual machine or container in the cloud environment.

The first device 600 includes a processor 601, memory 602, storage 603, input interface IF (Interface) 604, output IF 605, communication IF 606, and bus 607. Each component is configured to communicate with each other via the bus 607.

The processor 601 can execute programs to realize various functions of the support mark inspection equipment 100. The processor 601 is composed of at least one integrated circuit, for example. According to one embodiment, the integrated circuit may include at least one CPU (Central Processing Unit), at least one GPU (Graphics Processing Unit), at least one FPGA (Field Programmable Gate Array), at least one ASIC (Application Specific Integrated Circuit), at least one AI (Artificial Intelligence) chip, or combinations thereof.

The memory 602 functions as the workspace for the processor 601. The memory 602 stores programs executed by the processor 601 and data referenced by the processor 601. The memory 602 may be implemented using DRAM (Dynamic Random Access Memory) or SRAM (Static Random Access Memory), etc.

The storage 603 is non-volatile memory that stores programs executed by the processor 601 and data referenced by the processor 601. The processor 601 executes programs read from the storage 603 into the memory 602 and references data read from storage 603 into the memory 602. The storage 603 may be implemented using HDD (Hard Disk Drive), SSD (Solid State Drive), EPROM (Erasable Programmable Read Only Memory), EEPROM (Electrically Erasable Programmable Read Only Memory), or flash memory, etc.

The input IF 604 may be connected to any input device such as a keyboard, mouse, touchpad, or gamepad. The input IF 604 may be implemented using USB terminals, PS/2 terminals, and Bluetooth (registered trademark) modules, etc.

The output IF 605 may be connected to any output device such as a CRT display, LCD display, or OLED display. The output IF 605 may be implemented using USB terminals, D-sub terminals, DVI (Digital Visual Interface) terminals, HDMI (registered trademark) (High-Definition Multimedia Interface) terminals, and DisplayPort terminals, etc.

The communication IF 606 is connected to other devices via wired or wireless networks. The communication IF 606 may be implemented using wired LAN (Local Area Network) ports and Wi-Fi (registered trademark) (Wireless Fidelity) modules, etc. The communication IF 606 can send and receive data using communication protocols such as TCP/IP (Transmission Control Protocol/Internet Protocol) and UDP (User Datagram Protocol).

The storage 603 stores the inspection program 610. The inspection program 610 is a program for realizing function blocks other than the AI model 510 in FIG. 5. The inspection program 610 is configured to communicate with the AI model 510 via the communication IF 606.

The second device 620 includes a processor 621, a memory 622, a storage 623, an input IF 624, an output IF 625, a communication IF 626, and a bus 627. These components are configured to communicate with each other via the bus 607. Since each hardware provided by the second device 620 is identical to each hardware provided by the first device 600, the description of this hardware will not be repeated. The storage 623 stores AI model 510. The AI model 510 is configured to communicate with the inspection program 610 via the communication IF 626.

### Processing Executed by Support Mark Inspection Device

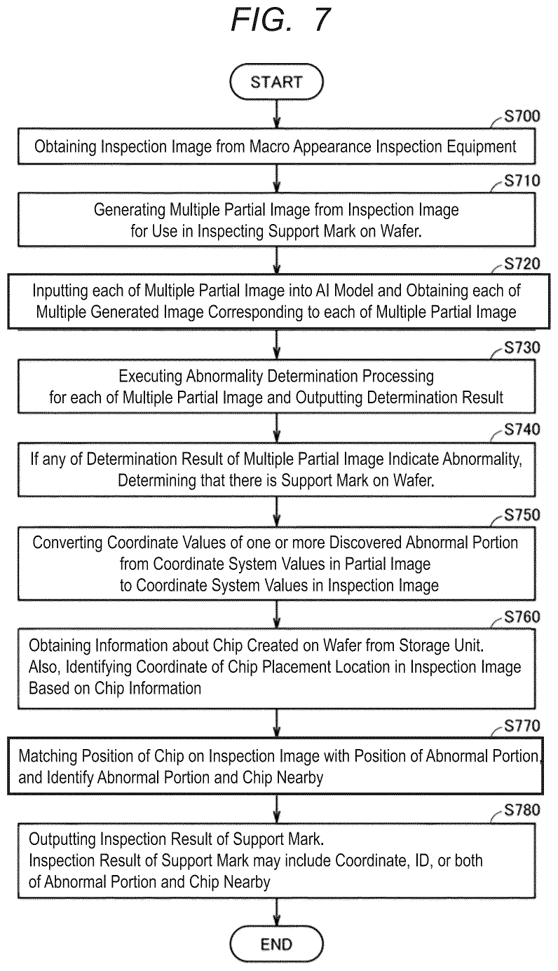

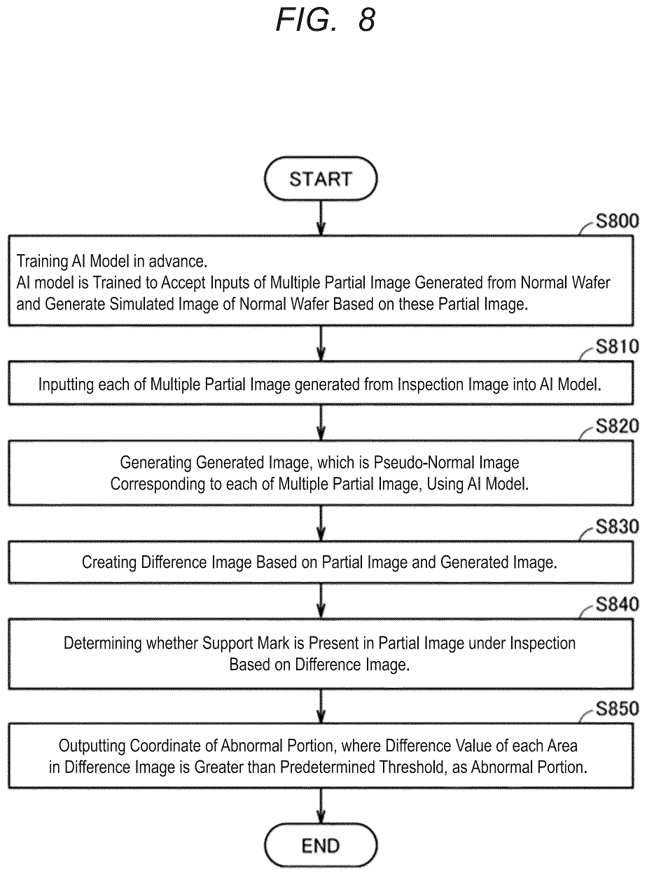

The processor 601 of the first device 600 may read the inspection program 610 from the storage 603 into the memory 602 and execute the processing of FIG. 7 and FIG. 8. Similarly, the processor 621 of the second device 620 may read the AI model 510 from the storage 623 into the memory 622 and execute the processing handled by the AI model 510 within the processing of FIG. 7 and FIG. 8. Part or all of the processing in FIG. 7 and FIG. 8 may also be implemented as a combination of circuit elements configured to execute the processing. Each of the processing in FIG. 7 and FIG. 8 may be executed in a different order.

FIG. 7 is a diagram illustrating an example of the detection processing of the support mark 50 on the wafer 20 by the support mark inspection equipment 100. In step S700, the support mark inspection equipment 100 acquires the inspection image 200 from the macro appearance inspection device 300. In step S710, the support mark inspection equipment 100 generates multiple partial images 350 from the inspection image 200 for use in inspecting the support mark 50 on the wafer 20. In step S720, the support mark inspection equipment 100 inputs each of the multiple partial images 350 into the AI model 510 and acquires each of the multiple generated images 450 corresponding to each of the multiple partial images 350.

In step S730, the support mark inspection equipment 100 executes abnormality determination processing for each of the multiple partial images 350 and outputs the determination result. As an example, the support mark inspection equipment 100 executes the processing shown in step S840 of FIG. 8 as abnormality determination processing. If the determination result indicates an abnormality, the support mark inspection equipment 100 outputs the coordinates of the abnormal portion within the partial image 350 under inspection.

In step S740, if any of the determination results of the multiple partial images 350 indicate an abnormality, the support mark inspection equipment 100 determines that there is a support mark 50 on the wafer 20. In step S750, the support mark inspection equipment 100 converts the coordinate values of one or more discovered abnormal portions from the coordinate system values in the partial image 350 to the coordinate system values in the inspection image 200.

In step S760, the support mark inspection equipment 100 acquires information about the chips created on the wafer 20 from storage unit 504. The support mark inspection equipment 100 identifies the coordinates of the chip placement location in the inspection image 200 based on the chip information. The placement location may indicate the range where chips are placed or the boundary between chips. The boundary between chips may be the boundary between dies. In this case, the coordinates of each chip may include all or part of the coordinates indicating each vertex of a rectangle, as an example.

In step S770, the support mark inspection equipment 100 matches the position of the chips on the inspection image 200 with the position of the abnormal portions and identifies the abnormal portions and the chips nearby. In step S780, the support mark inspection equipment 100 outputs the inspection results of the support mark 50. The inspection results of the support mark 50 may include the coordinates, ID, or both of the abnormal portions and the chips nearby. Additionally, the inspection results of the support mark 50 may include the coordinates of individual support marks 50. Furthermore, the inspection results of the support mark 50 may include information indicating the presence or absence of support marks 50 (i.e., abnormal portions) in each partial image 350 or inspection image 200.

FIG. 8 is a diagram illustrating an example of the learning process of the AI model 510 and the details of the processing from step S720 to S740. In step S800, the support mark inspection equipment 100 pre-trains the AI model 510. More specifically, the AI model 510 is trained to accept inputs of multiple partial images 350 generated from a normal wafer 20 and generate simulated images of the normal wafer 20 based on these partial images 350. The training of the AI model 510 may be executed by other devices. In this case, the support mark inspection equipment 100 receives the trained AI model 510 from other devices. Alternatively, other devices may store a copy of the trained AI model 510 in the storage 623 of the support mark inspection equipment 100.

In step S810, the support mark inspection equipment 100 inputs each of the multiple partial images 350 generated from the inspection image into the AI model 510.

In step S820, the support mark inspection equipment 100 generates a generated image 450, which is a pseudo-normal image corresponding to each of the multiple partial images 350, using the AI model 510. The generated image 450 is a partial image from which the abnormal portion, the support mark 50, has been removed from the corresponding partial image 350.

In step S830, the support mark inspection equipment 100 creates a difference image 460 based on the partial image 350 and the generated image 450. The difference between the portion without the support mark 50 (i.e., the normal portion) in the partial image 350 and the corresponding part of the generated image 450 becomes almost zero. On the other hand, the difference between the portion with the support mark 50 (i.e., abnormal portion) in the partial image 350 and the corresponding part of the generated image 450 becomes a large value. As a result, the difference image 460 becomes data filtered to exclude parts other than those with the support mark 50.

In step S840, the support mark inspection equipment 100 determines whether the support mark 50 is present in the partial image 350 under inspection based on the difference image 460. As an example, the support mark inspection equipment 100 calculates the total value of the value (difference value of corresponding portions of the partial image 350 and the generated image 450) of each portion from the difference image 460. Each part may be represented as a pixel. The support mark inspection equipment 100 determines whether the total value is greater than a predetermined threshold (threshold of the total value). If the total value is greater than the predetermined threshold (threshold of the total value), the support mark inspection equipment 100 determines that the support mark 50 is present in the partial image 350 under inspection (i.e., determines that there is an abnormality in the partial image 350 under inspection). As another example, the support mark inspection equipment 100 may determine whether the value of each area in the difference image 460 is greater than a predetermined threshold (threshold of the difference value of each area). In this case, if there are areas with values greater than the predetermined threshold in the difference image 460 that exceed a predetermined number, it is determined that the support mark 50 is present in the partial image 350 under inspection (i.e., it is determined that there is an abnormality in the partial image 350 under inspection).

In step S850, the support mark inspection equipment 100 outputs the coordinate of the abnormal portion, where the difference value of each area (pixel) in the difference image 460 is greater than the predetermined threshold, as the abnormal portion. The coordinate of the abnormal portion is the coordinate in the coordinate system of the partial image 350.

As explained with reference to FIGS. 7 and 8 (Support for claims 6 and 7), the support mark inspection equipment 100 can execute a method for inspecting the presence of the support mark 50 on the wafer 20 by executing a program. The method includes:
obtaining the inspection image 200 of the wafer 20: and extracting the plurality of partial images 350 from the inspection image 200. Each of the plurality of partial images 350 includes the portion where the support portion 22 of the boat 12 contacts the wafer 20. The method further includes: inputting each of the plurality of partial images 350 into the AI (Artificial Intelligence) model 510 and obtaining the plurality of generated images 450 respectively corresponding to the plurality of partial images 350; determining whether the support mark 50 is present in each of the plurality of partial images 350 based on each of the plurality of partial images 350 and each of the plurality of generated images 450; and outputting the inspection result based on the determination of whether the support mark is present.

### SUMMARY

The support mark inspection equipment 100 creates multiple partial images 350 from the inspection image 200, including the area 24 that contacts support portion 22. Then, the support mark inspection equipment 100 analyzes each of the multiple partial images 350 to determine the presence of the support mark 50. By doing so, the support mark inspection equipment 100 can determine the presence of the support mark 50 with higher accuracy than directly analyzing the inspection image 200.

The disclosed embodiment should be considered illustrative in all respects and not restrictive. The scope of the present disclosure is indicated by the Claims rather than the above description, and it is intended that all changes within the meaning and range equivalent to the Claims are included. Furthermore, the disclosed content described in the embodiment and each modified example is intended to be implemented alone or in combination as much as possible.

What is claimed is:

1. A support mark inspection equipment comprising:
an input unit for obtaining an inspection image of a wafer;
a partial image generating unit for extracting a plurality of partial images, each including a portion where a support portion of a boat contacts the wafer, from the inspection image;
a generated image obtaining unit for inputting each of the plurality of partial images into an AI (Artificial Intelligence) model and obtaining a plurality of generated images respectively corresponding to the plurality of partial images;
an abnormality determination unit for determining whether a support mark is present in each of the plurality of partial images based on each of the plurality of partial images and each of the plurality of generated images; and
an output unit for outputting an inspection result of the support mark.

2. The support mark inspection equipment according to claim 1, wherein determining whether the support mark is present in each of the plurality of partial images includes specifying a coordinate of one or more abnormal portions containing the support mark in a partial image containing the support mark based on detecting result of the partial image containing the support mark.

3. The support mark inspection equipment according to claim 2, further comprising:
a coordinate conversion unit for converting a value of the coordinate of the one or more abnormal portions containing the support mark from a value of a coordinate system of the partial image containing the support mark to a value of a coordinate system in the inspection image;
a chip region identification unit for obtaining information of chips formed in alignment on the wafer and identifying a plurality of regions in which the chips are respectively arranged; and
a defective chip identification unit for identifying a defective chip formed in a region containing the one or more abnormal portions containing the support mark based on a converted coordinate of the one or more abnormal portions and the plurality of regions.

4. The support mark inspection equipment according to claim 1, wherein each of the plurality of generated images is an image that mimics an image expected to be obtained when the support mark is not present in each of the plurality of partial images.

5. The support mark inspection equipment according to claim 4, wherein the determining whether the support mark is present in each of the plurality of partial images includes:
generating a difference image between an inspection target partial image, which is one of the plurality of partial images, and one of the plurality of generated images corresponding to the inspection target partial image;
determining whether the support mark is present in the inspection target partial image based on a difference value contained in the difference image; and
extracting one or more coordinates, where the difference value is equal to or greater than a predetermined threshold, from the difference image based on determining result that the support mark is present in the inspection target partial image.

6. A method for inspecting the presence of a support mark on a wafer in an equipment, comprising:
obtaining an inspection image of the wafer;
extracting a plurality of partial images, each including a portion where a support portion of a boat contacts the wafer, from the inspection image;
inputting each of the plurality of partial images into an AI (Artificial Intelligence) model and obtaining a plurality of generated images respectively corresponding to the plurality of partial images;
determining whether the support mark is present in each of the plurality of partial images based on each of the plurality of partial images and each of the plurality of generated images; and
outputting an inspection result based on a determination of whether the support mark is present.

7. A non-transitory tangible machine-readable medium having stored thereon a program for causing an equipment to perform an inspection of the presence of a support mark on a wafer, the inspection including:
obtaining an inspection image of the wafer;
extracting a plurality of partial images, each including a portion where a support portion of a boat contacts the wafer, from the inspection image;
inputting each of the plurality of partial images into an AI (Artificial Intelligence) model and obtaining a plurality of generated images respectively corresponding to the plurality of partial images;
determining whether the support mark is present in each of the plurality of partial images based on each of the plurality of partial images and each of the plurality of generated images; and
outputting an inspection result based on a determination of whether the support mark is present.
